(19) United States
(12) Patent Application Publication
(10) Pub. No.: US 2026/0059736 A1
(43) Pub. Date: Feb. 26, 2026

(54) SYSTEM AND METHODS FOR A DUAL CYLINDER CAPACITOR

(71) Applicant: Samsung Electronics Co., Ltd., Suwon-si (KR)

(72) Inventor: Wangee KIM, Dublin, CA (US)

(21) Appl. No.: 19/093,242

(22) Filed: Mar. 27, 2025

Related U.S. Application Data
(60) Provisional application No. 63/686,723, filed on Aug. 23, 2024.

(51) Int. Cl. H10B 12/00

(52) U.S. Cl. CPC H10B 12/30; H10B 12/03

(57) ABSTRACT

Disclosed herein are methods, devices and systems including a first electrode forming a first structure, the first structure having a first segment and a second segment extending in a direction parallel to the first segment; a second electrode forming a second structure, the second structure having a third segment and a fourth segment with the first segment arranged between the third segment and the second segment, the second structure being concentric with the first structure; the first structure and the second structure forming a first capacitor; a first dielectric material arranged on a side of the first electrode opposite the second electrode; an intermediate dielectric material between the first electrode and the second electrode, the intermediate dielectric material supporting the second electrode; and a conductive plug contacting the second electrode so that the first structure is concentric of the conductive plug.

### CROSS-REFERENCE TO RELATED APPLICATION

This application claims the priority benefit under 35 U.S. C. § 119(e) of U.S. Provisional Patent Application Ser. No. 63/686,723 filed on Aug. 23, 2024, the disclosure of which is incorporated herein by reference in its entirety.

### TECHNICAL FIELD

The subject matter disclosed herein relates to microelectronics and integrated circuits (IC) structures. More particularly, the subject matter disclosed herein relates to a semiconductor structure involving a dual cylinder capacitor structure.

### BACKGROUND

Semiconductor devices may be created using complex three-dimensional structures made up of sets of smaller components. Such components may include circuit components such as transistors, capacitors, etc. reproduced in large numbers and addressed using a matrix of intersecting lines. However, forming three-dimensional components is complex and may face difficulties in forming both the conductive portions and ensuring sufficient isolation between the individual conductors. It is further noted that background concepts discussed herein are for informational purposes only and are not intended to limit the present disclosure. Nor should the background or field described herein be intended to limit the disclosure herein to a particular use or concept.

### SUMMARY

An example embodiment provides a device including a first electrode forming a first structure, the first structure having a first segment and a second segment extending in a direction parallel to the first segment; a second electrode forming a second structure, the second structure having a third segment and a fourth segment with the first segment arranged between the third segment and the second segment, the second structure being concentric with the first structure; the first structure and the second structure forming a first capacitor; a first dielectric material arranged on a side of the first electrode opposite the second electrode; an intermediate dielectric material between the first electrode and the second electrode, the intermediate dielectric material supporting the second electrode; and a conductive plug contacting the second electrode so that the first structure is concentric of the conductive plug. In some embodiments, the first dielectric may include one or more of a carbide, a nitride or an oxide. In some embodiments, the first electrode is coupled to a source, the second electrode is coupled to a drain, a transistor is between the first electrode and the source, and the first electrode, the second electrode and the transistor form a memory cell. In some embodiments, the intermediate dielectric material has a higher dielectric constant than silicon oxide. In some embodiments, the intermediate dielectric material conformally covers the first dielectric, and the second electrode conformally covers the intermediate dielectric material. In some embodiments, the intermediate dielectric material conformally covers a first side of the second electrode and the conductive plug extends on a second side of the second electrode, the second side opposite the first side, and extends parallel to the intermediate dielectric material. In some embodiments, a second electrode includes a fifth segment and a sixth segment parallel to the fifth segment, and the second segment is between the fifth segment and the sixth segment.

An example embodiment provides a system including a first electrode forming a first capacitive structure, the first capacitive structure contacting a first dielectric material on a first side; a second electrode forming a second capacitive structure, the second capacitive structure having an axial opening; a second dielectric material arranged between the first capacitive structure and the second capacitive structure, the second dielectric material located on a second side of the first capacitive structure, the second side opposite the first side; a conductive layer forming conductive plug within the axial opening of the second capacitive structure, and the first capacitive structure and the second capacitive structure are coaxial. In some embodiments, the second dielectric material has a higher dielectric constant than silicon oxide. In some embodiments, the second dielectric material conformally coats the first electrode and the second electrode conformally coats the second dielectric material. In some embodiments, the second capacitive structure is concentric with the conductive plug. In some embodiments, a third electrode forms a third capacitive structure, the second electrode forms a fourth capacitive structure arranged coaxially with the third capacitive structure, the second dielectric material is between the third capacitive structure and the fourth capacitive structure, the fourth capacitive structure has a second axial opening, and the conductive layer forms a second conductive plug within the second axial opening of the fourth capacitive structure. In some embodiments, the first capacitive structure and the second capacitive structure may form a capacitor within a memory cell of a vertically stacked dynamic random-access memory.

An example embodiment provides a method including forming a mold within a first dielectric, depositing a first conductor to conformally coat the mold, forming the first conductor into one or more first electrodes, forming an intermediate dielectric over the one or more first electrodes, depositing a second conductor over the intermediate dielectric to form one or more second electrodes, where the one or more first electrodes are separated by the first dielectric and the one or more second electrodes form a continuous layer. In some embodiments, the first dielectric includes one or more of a carbide, nitride, or oxide, and the intermediate dielectric may include a material having a higher dielectric constant than silicon oxide. In some embodiments, depositing the second conductor may be done conformally, and depositing the intermediate dielectric may be done conformally. In some embodiments, after depositing the second conductor, a plate conductor layer may be deposited over the second conductor. In some embodiments, forming the mold within the first dielectric is done in a lateral direction. In some embodiments, forming the first conductor into one or more first electrodes includes removing portions of the first conductor between each of the one or more first electrodes. In some embodiments, the intermediate dielectric forms a continuous layer between the one or more first electrodes and the one or more second electrodes.

### BRIEF DESCRIPTION OF THE DRAWING

In the following section, the aspects of the subject matter disclosed herein will be described with reference to example embodiments illustrated in the figures, in which:

FIG. 1 depicts a perspective view of a semiconductor structure according to various embodiments of the subject matter disclosed herein;

FIG. 2A depicts a perspective cross-section view of a semiconductor structure according to various embodiments of the subject matter disclosed herein;

FIG. 2B depicts a plan view of a semiconductor structure according to various embodiments of the subject matter disclosed herein;

FIG. 2C depicts a cross-section view of a semiconductor structure according to various embodiments of the subject matter disclosed herein;

FIG. 2D depicts a cross-section view of a semiconductor structure according to various embodiments of the subject matter disclosed herein;

FIG. 2E depicts a cross-section view of a semiconductor structure according to various embodiments of the subject matter disclosed herein;

FIGS. 3A-3S depict cross-section views of an example embodiment of a semiconductor structure at different stages of its manufacture; and

FIG. 4 depicts a plan view of a method forming a semiconductor structure according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration. ” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Disclosed herein are various embodiments of devices, systems and methods related to a dual cylinder capacitor within a 3D memory device. A 3D memory device may have an array of cells including a pair of electrodes spaced apart by a dielectric, the pair of electrodes forming a capacitor. The pair of electrodes may be referred to as a bottom electrode and a top electrode. The bottom electrode may be formed in a cylindrical shape, with a center opening and a rim around the opening. The top electrode may be formed in a similar manner, but complementary to the bottom electrode such that the entire bottom electrode, and an intermediate layer of dielectric materials, may be covered by the top electrode. The dual cylinder capacitor structure may be formed by first preparing a molding structure with a first dielectric surrounding a second dielectric. The second dielectric may be patterned to form a mold. The bottom electrode may be then formed within that mold. The first dielectric may be then partially recessed to expose the bottom electrode. The remainder of the second dielectric may then be removed. Then the intermediate dielectric material may be formed over the exposed bottom electrode and portions of the first dielectric. Afterwards, the top electrode may be formed over the intermediate dielectric materials.

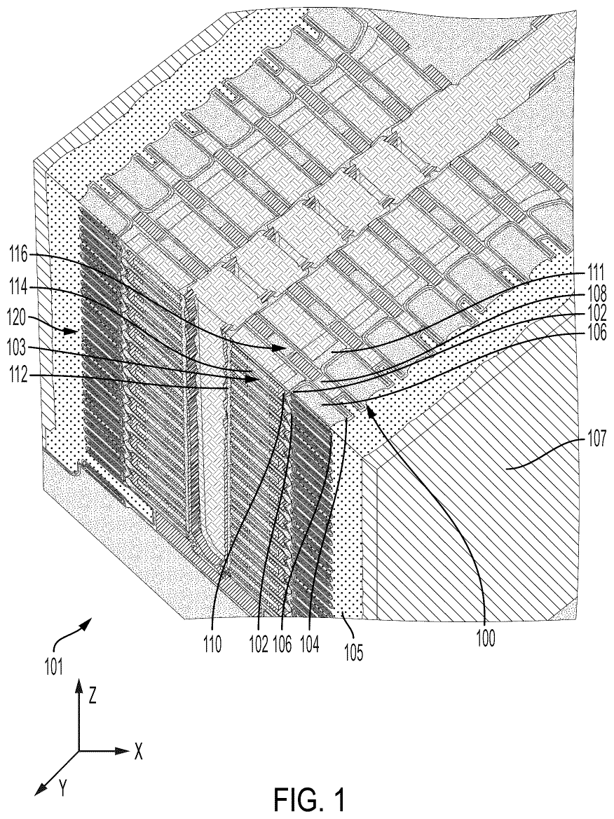

FIG. 1 depicts a perspective view of an example embodiment of a first device architecture 101. The first device architecture 101 may form a portion of a 3D memory device, as well as any other suitable three-dimensional semiconductor devices. In the example of FIG. 1, the 3D memory device may take the form of a vertically stacked device, where individual device layers 120 may be stacked upon each other. In some embodiments, the individual device layers 120 may take the form of a memory device such as dynamic random-access memory (DRAM), with the resulting 3D memory device of the first device architecture 101 taking the form of a vertically stacked DRAM. However, in other embodiments, the form of the individual device layers 120 may vary, and may include one or more layers such as static random-access memory (SRAM), synchronous dynamic random-access memory (SDRAM), double data rate DRAM or DDR DRAM, flash memory, read only memory (ROM), programmable read only memory (PROM), electronically programmable read only memory (EPROM), electronically erasable and programmable read only memory (EEPROM), phase-change random-access memory (Phase-change RAM), ferroelectric random-access memory (FRAM), and resistive random-access memory (RRAM), or any other suitable memory devices, either alone or in combination. In the example embodiment of FIG. 1, the individual device layers 120 may be substantially similar to each other, while in other embodiments, the individual device layers 120 may differ from each other.

In the first device architecture 101, the addressing of individual elements such as capacitors, memory cells, or other suitable elements, may be done by use of one or more vertical electrodes 112 and one or more horizontal electrodes 114 to provide signals to one or more capacitors 100. In the example embodiment of FIG. 1, the one or more vertical electrodes 112 extend parallel to the Z-axis, while the one or more horizontal electrodes 114 extend parallel to the Y-axis, and one or more capacitors 100 extend substantially to the X-axis. In some embodiments, each vertical electrode 112 may be used as a bit line and each horizontal electrode 114 may be used as a word line. In other embodiments, each vertical electrode 112 may be used as the word line and each horizontal electrode 114 may be used as a bit line. The one or more capacitors 100 may be connected to one or more transistors 116, to form one or more memory cells 103. In some embodiments, the one or more horizontal electrodes 114 may be coupled with one or more transistors 116 prior to the one or more capacitors 100. As used herein, terms such as bit line, word line, read line, address line, grid, array, and matrix may be used interchangeably to describe the various electrodes organized to provide a signal where two lines intersect within a larger device.

As shown in FIG. 1, and discussed below in more detail, the one or more capacitors 100 each include a bottom electrode 102, a top electrode 106, and an intermediate dielectric 104. Although referred to as the bottom electrode 102 and the top electrode 106, the actual orientation with respect to the individual electrodes may vary. In some embodiments, the bottom electrode 102 may be coupled to the one or more transistors 116, the one or more horizontal electrodes 114, and the one or more vertical electrodes 112, with the bottom electrode 102 receiving an electrical charge via an addressing matrix formed by the one or more vertical electrodes 112 and the one or more horizontal electrodes 114. The top electrode 106 may, in some embodiments, contact a plate conductor 105 which may, in some embodiments, act as the drain for the one or more capacitors 100. In some embodiments, the bottom electrode 102 thus may be referred to as the source-side electrode and the top electrode 106 may be referred to as the drain side electrode. The plate conductor 105 may may include metals such as tungsten, aluminum, titanium. In some embodiments, the conductive material of the plate conductor 105 may be formed by a semiconductor process such as chemical vapor deposition (CVD), atomic layer deposition (ALD), physical vapor deposition (PVD), electroplating, or any other suitable method for forming a conductive material. In some embodiments the plate conductor 105 may be formed of more than one layer, for example a liner layer or a glue layer prior to a bulk layer. In some embodiments, a second plate conductor 107 may be formed as the contact. The plate conductor 105 and the second plate conductor 107 may be formed from any suitable metal, including titanium, titanium nitride, tungsten, tungsten nitride, and combinations thereof. In some embodiments, the conductor may include a combination of materials, including oxides and nitrides. Such a listing of elements is not intended to be exhaustive, and in other embodiments, any known other type of conductive material may be used.

Although referred to as the drain side and the source side, in some embodiments, bottom electrode 102 may act as the drain, and the top electrode 106 may act as the source. The bottom electrode 102 and the top electrode 106 may be made of a suitable conductive material for use in semiconductor processing, for example a semiconductor material such as a conductive silicon material like doped silicon, as well as metals, or any other suitable conductor, alone or in combination. In some embodiments, the bottom electrode 102 and the top electrode 106 may be made of substantially the same material, while in other embodiments the bottom electrode 102 and the top electrode 106 may be made of different materials.

The intermediate dielectric 104 may separate the bottom electrode 102 and the top electrode 106 and, based on the dielectric constant and thickness of the dielectric material of the intermediate dielectric 104, may determine the amount of charge each of the one or more capacitors 100 may store. In some embodiments, the intermediate dielectric 104 may include semiconductor materials, as well as nitrides, carbides, and oxides thereof, and may consist of silicon nitride, silicon dioxide, or other similar materials such as gallium nitride, gallium oxide, and so forth. In some embodiments, the intermediate dielectric 104 may consist of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide.

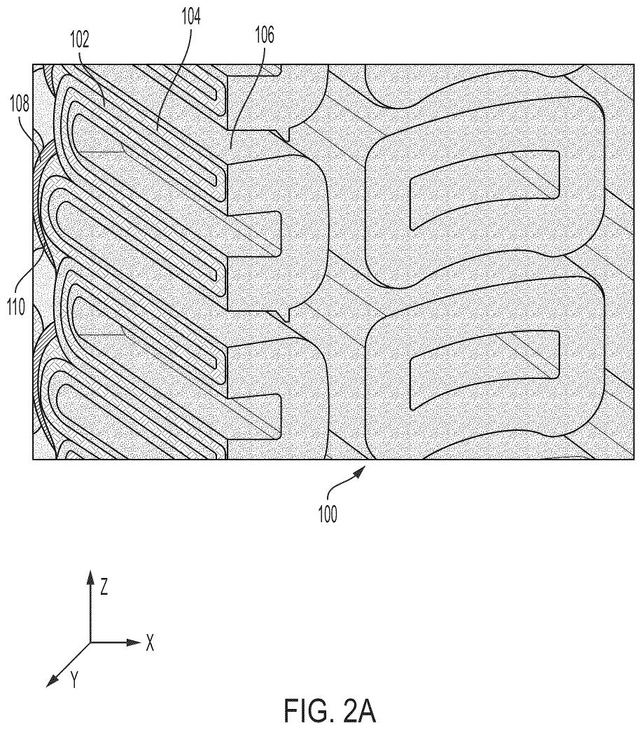

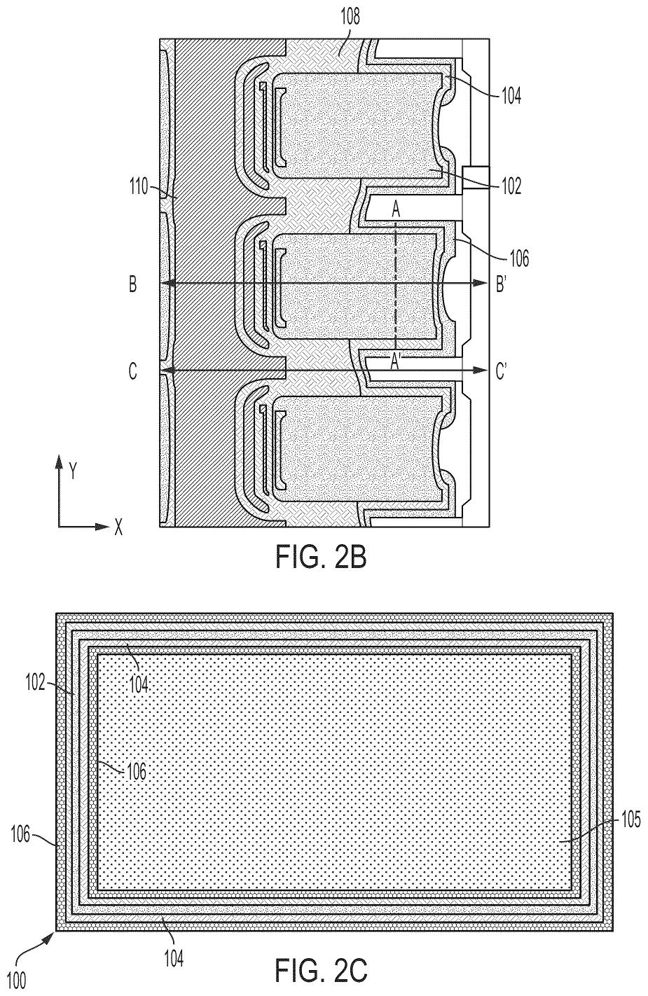

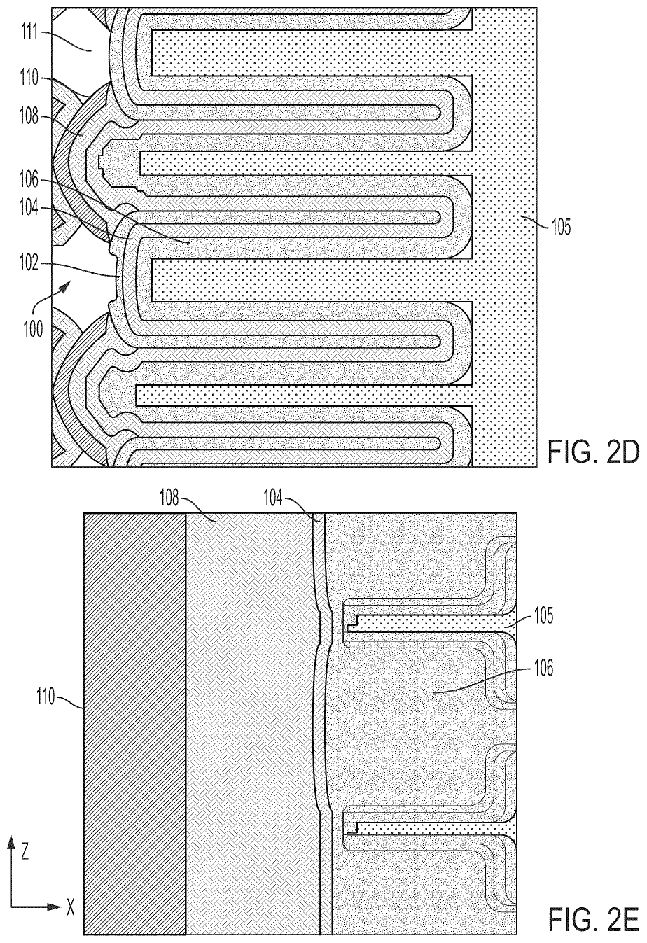

As shown in FIG. 1, as well as in more detail in FIG. 2A, a number of different materials may be used to provide isolation and support, including a first dielectric material 108, a second dielectric material 110 and a liner material 111. In some embodiments, the dielectric material used to form the first dielectric material 108 and the second dielectric material 110 may include semiconductor materials, as well as nitrides, carbides, and oxides thereof. In some embodiments, the first dielectric material 108 and the second dielectric material 110 may consist of silicon nitride (Si₃N₄) or silicon dioxide (SiO₂, or other similar materials such as gallium nitride, gallium oxide, and so forth. In some embodiments, the first dielectric material 108 and the second dielectric material 110 may consist of the same dielectric material, while in other embodiments, the first dielectric material 108 and the second dielectric material 110 may consist of different materials. The liner material 111 may, in some embodiments, correspond to a dielectric material such as used in either of the first dielectric material 108 and the second dielectric material 110, while in other embodiments, the liner material 111 may consist of semiconductor materials such as silicon, germanium, and combinations thereof. In some embodiments, the liner material 111 may consist of a conductive material such as a conductive silicon material like doped silicon, as well as metals like aluminum, titanium, or any other suitable conductor, alone or in combination. In some embodiments, the liner material 111 may electrically couple the one or more capacitors to the addressing matrix formed by the one or more vertical electrodes 112 and the one or more horizontal electrodes 114.

Segments of the first dielectric material 108 may be formed between each of the one or more capacitors 100, with the first dielectric material 108 contacting the bottom electrode 102 and portions of the intermediate dielectric 104. The first dielectric material 108 may provide for isolation between adjacent units of the one or more capacitors 100, providing electrical, physical, and thermal isolation between adjacent units of the one or more capacitors 100, and thus prevent shorts between the one or more capacitors 100. The second dielectric material 110 and the liner material 111 will be discussed with more detail below.

FIG. 2A depicts a perspective view of an example embodiment of the one or more capacitors 100, showing the arrangement of the one or more capacitors 100 as a set of open cylinders with the inner layer formed by the bottom electrode 102, which is surrounded by the intermediate dielectric 104, and the intermediate dielectric 104 is surrounded by the top electrode 106 forming an outer layer. Although referred to herein as a cylinder, the shape formed by the one or more capacitors 100 may vary, and include other shapes such as rectangular prisms, ovoids, tori, and other such shapes having an open center. In some embodiments, each of the one or more capacitors 100 may be regularly spaced apart from each other, with a pitch of 10-200 nm between each unit of the one or more capacitors 100, although in some embodiments, the pitch may be larger or smaller as desirable. Not shown in the perspective of FIG. 2A is the plate conductor 105, which may be used to fill the space surrounding the one or more capacitors 100 on the side of the top electrode 106.

FIG. 2B provides a cross-sectional view of an example embodiment of the one or more capacitors 100 with FIG. 2B differing from FIG. 2A by showing a view in the X-Y plane. FIG. 2B clarifies that the first dielectric material 108 may surround the end of the bottom electrode 102 distal from the top electrode 106. In the example view of FIG. 2B, the bottom electrode 102 is shown as a flat plate with the intermediate dielectric 104 and top electrode 106 forming a thin layer around the bottom electrode 102. FIG. 2B provides also the lines A-A′, B-B′ and C-C′, cross-sectional views along which are shown in FIG. 2C, FIG. 2D, and FIG. 2E, respectively.

FIG. 2C provides a cross-sectional view of an example embodiment of a single unit of one or more capacitors 100 in the Z-Y plane as along the line A-A′ in FIG. 2B. As shown in FIG. 2C, the bottom electrode 102 is surrounded on both the internal and external sides by the intermediate dielectric 104 and the top electrode 106. In the example of FIG. 2C, each of the one or more capacitors 100 has multiple capacitive relationships, as the four external sides of the top electrode 106 and the four internal sides of the top electrode 106 each have a capacitive relationship with the bottom electrode 102. The shape of the one or more capacitors 100, may thus, in some embodiments, altered to provide additional surface space between the top electrode 106 and the bottom electrode 102, and thus provide additional capacitance for each of the one or more capacitors 100. The one or more capacitors 100 may be formed into any suitable shape having symmetry, including cylinders, prisms, tori, etc.

FIG. 2D depicts a cross-sectional view of an example embodiment of a single unit of one or more capacitors 100 in the Z-X plane as along the line B-B′ in FIG. 2B. FIG. 2D shows a view of a cross section down the middle of the one or more capacitors 100, where the bottom electrode 102 has a U-shape. As shown in the example of FIG. 2D, the one or more capacitors 100 may each have one bottom electrode 102, with each U-shaped segment separated from the next set by the first dielectric material 108, the second dielectric material 110, the liner material 111, as well as the intermediate dielectric 104 and the top electrode 106. However, the top electrode 106 and the intermediate dielectric 104 may form continuous surfaces and extend between each bottom electrode 102. Bottom electrodes 102 may thus be insulated from each other, and provide each of the one or more capacitors 100 with an area to store charge.

FIG. 2E depicts a cross-sectional view of an example embodiment of a single unit of one or more capacitors 100 in the Z-X plane as along the line C-C′ in FIG. 2B. The example view of FIG. 2E is taken from within the area between each bottom electrode 102, and thus between each unit of the one or more capacitors 100. The top electrode 106 is in contact with the intermediate dielectric 104, which in turn is in contact with the first dielectric material 108 and the second dielectric material 110. As the top electrode 106 may act as the drain for the one or more capacitors 100, the top electrode 106 contacting multiple units of the one or more capacitors 100 may provide for a consistent bias to the capacitive structure.

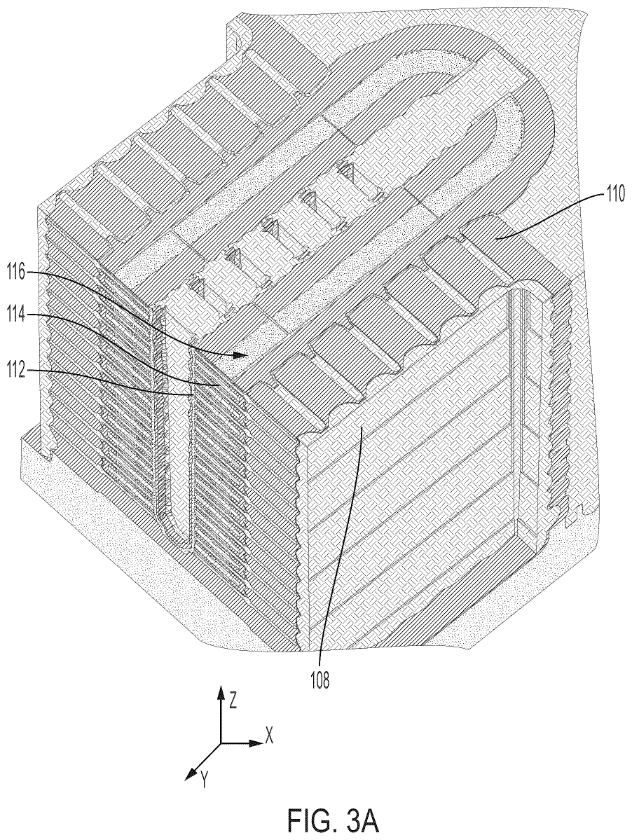

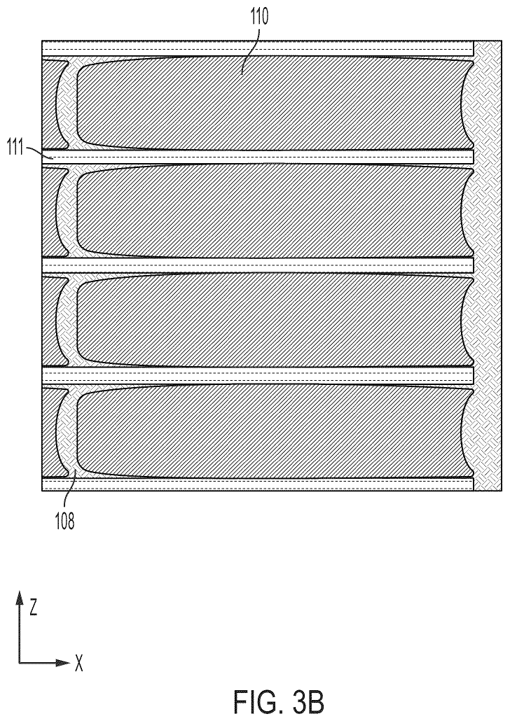

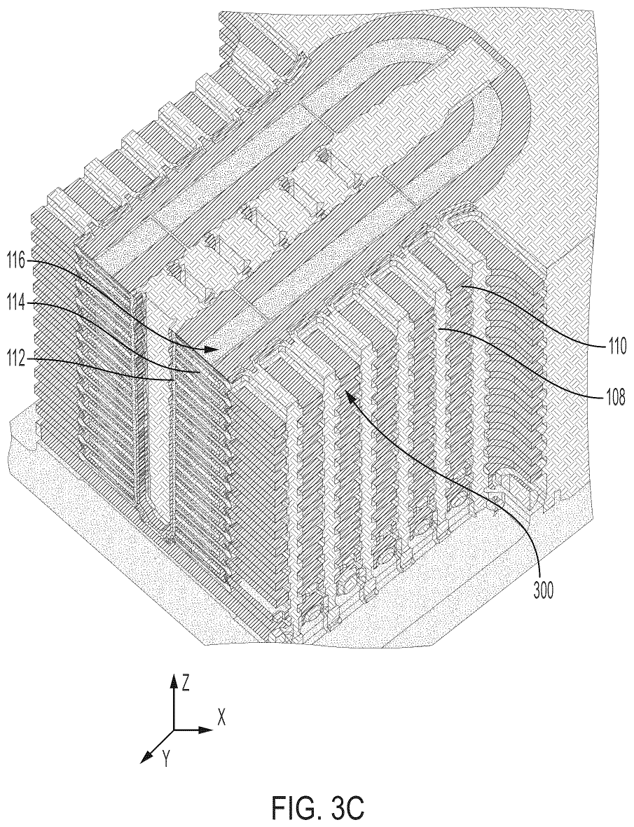

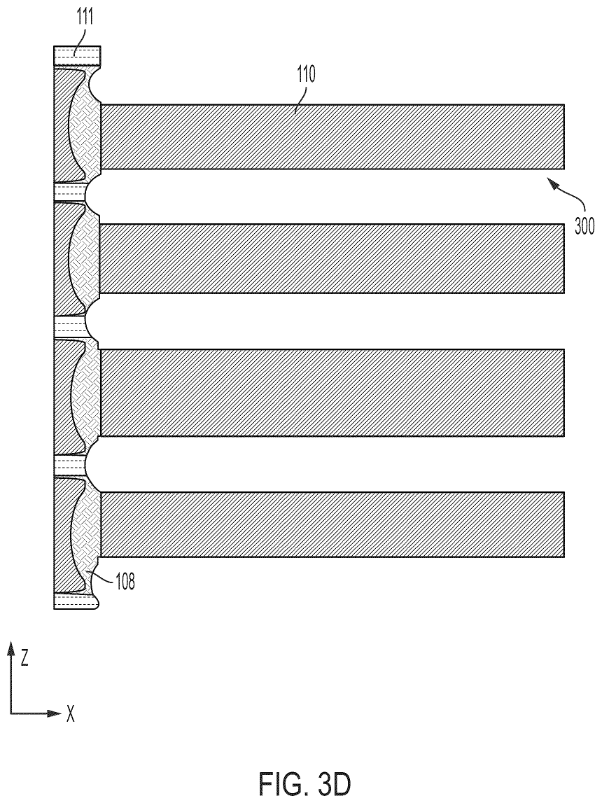

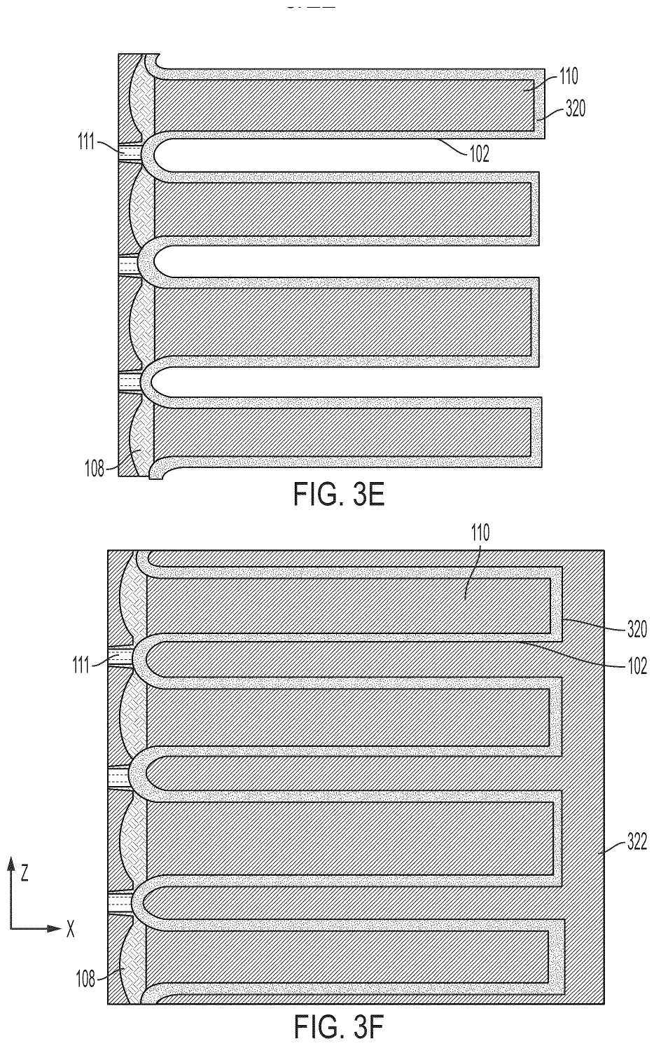

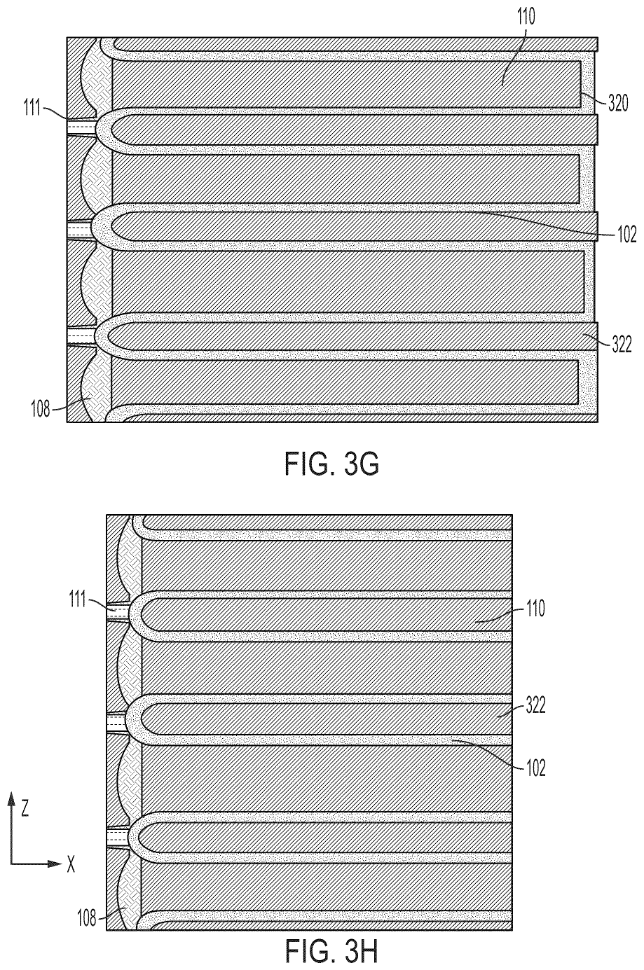

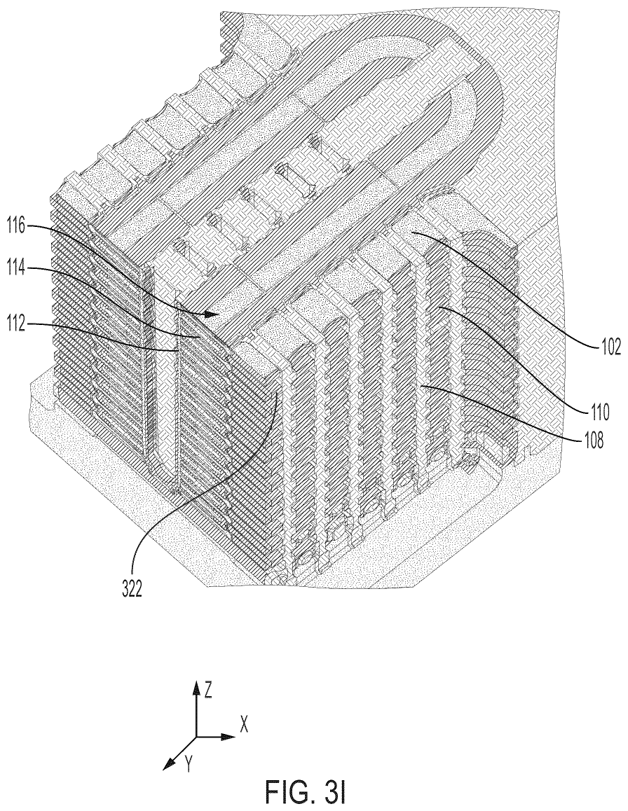

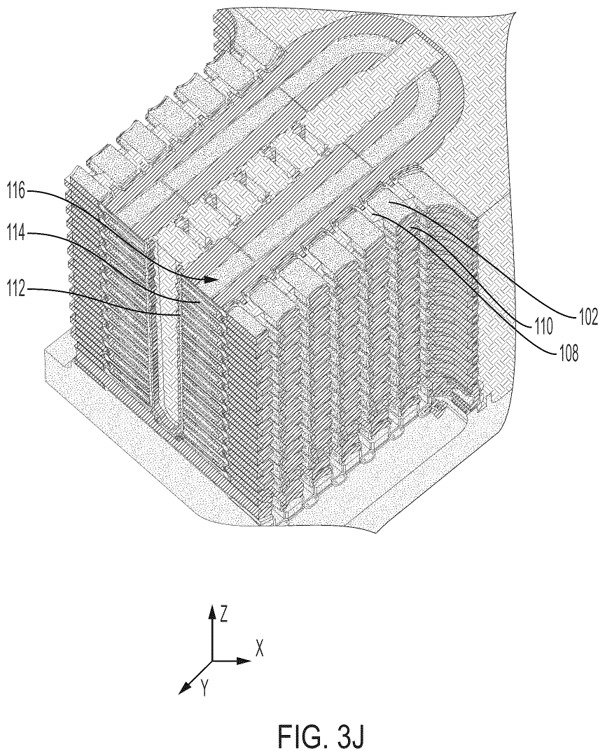

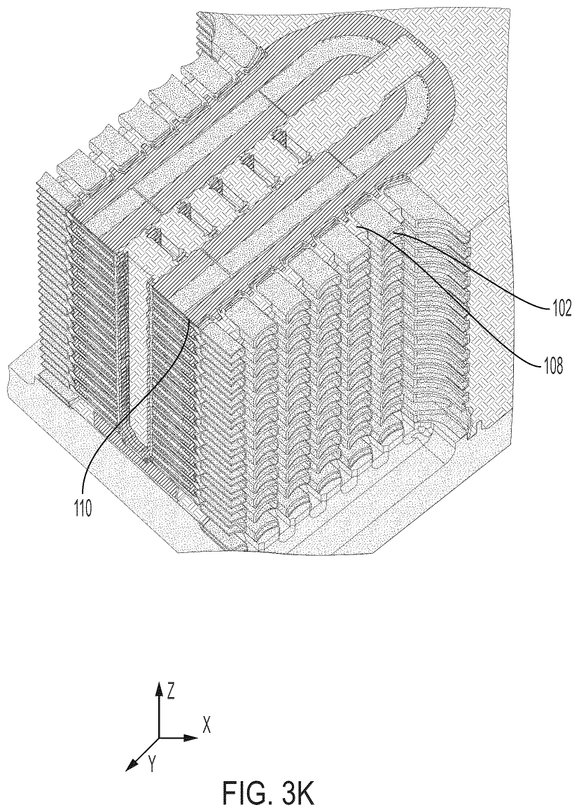

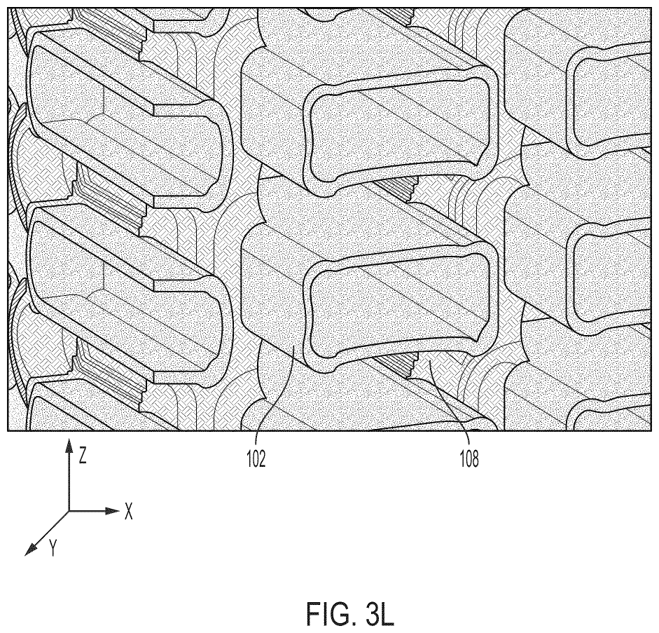

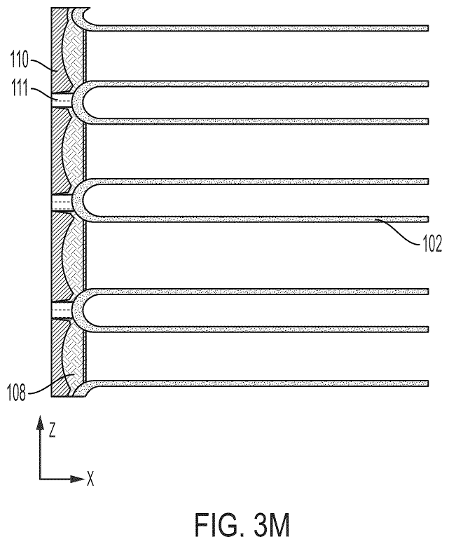

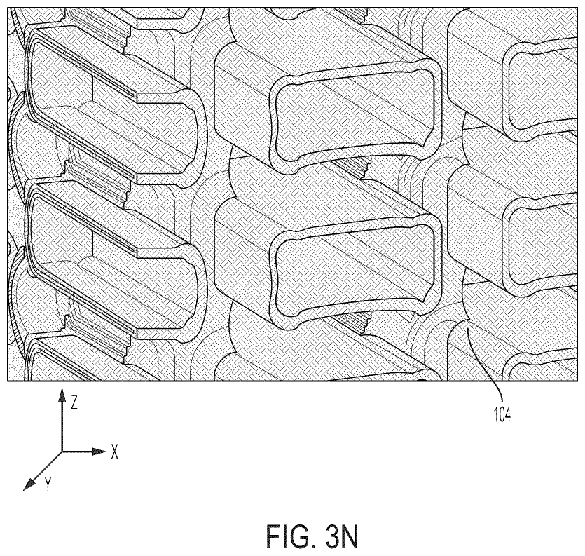

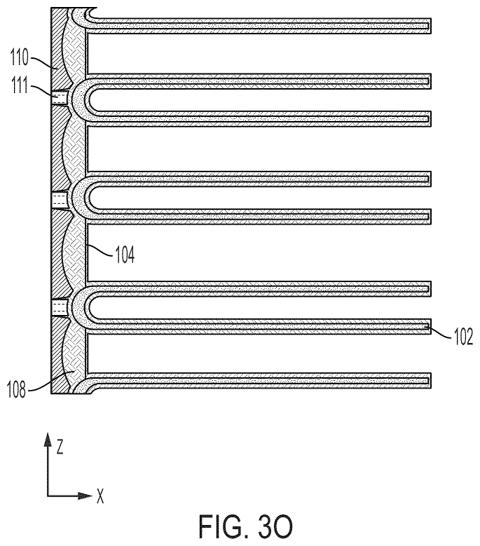

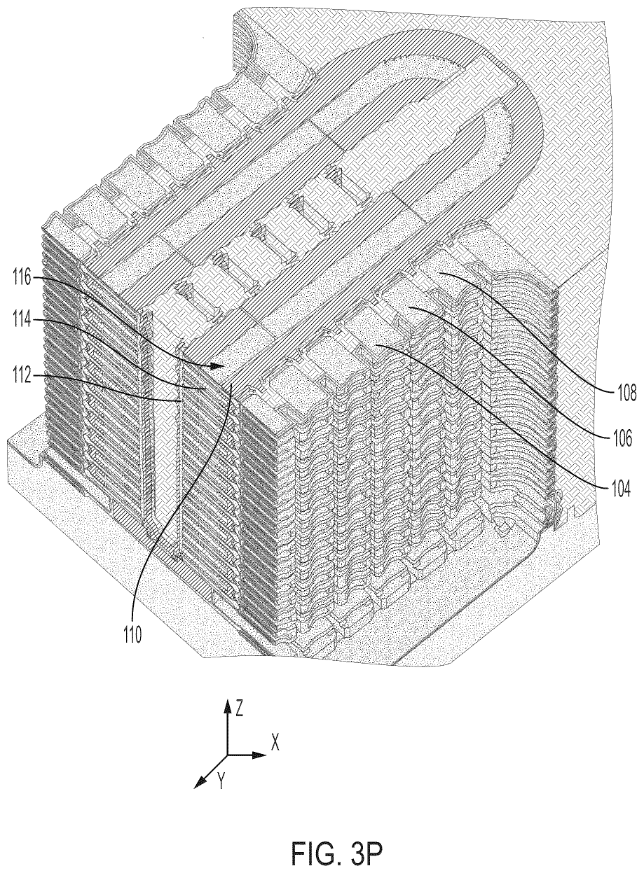

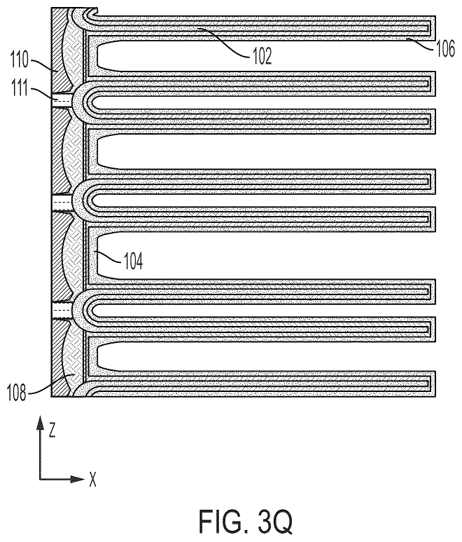

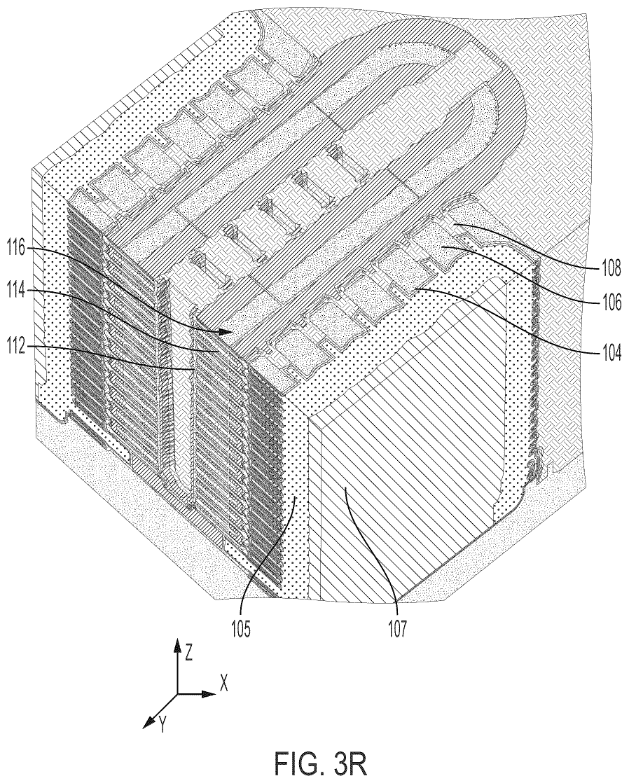

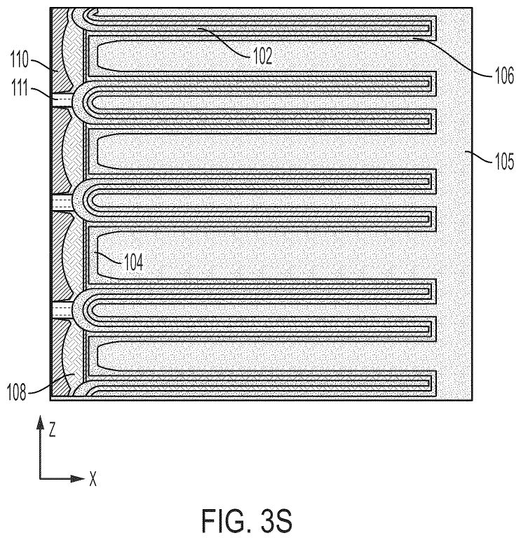

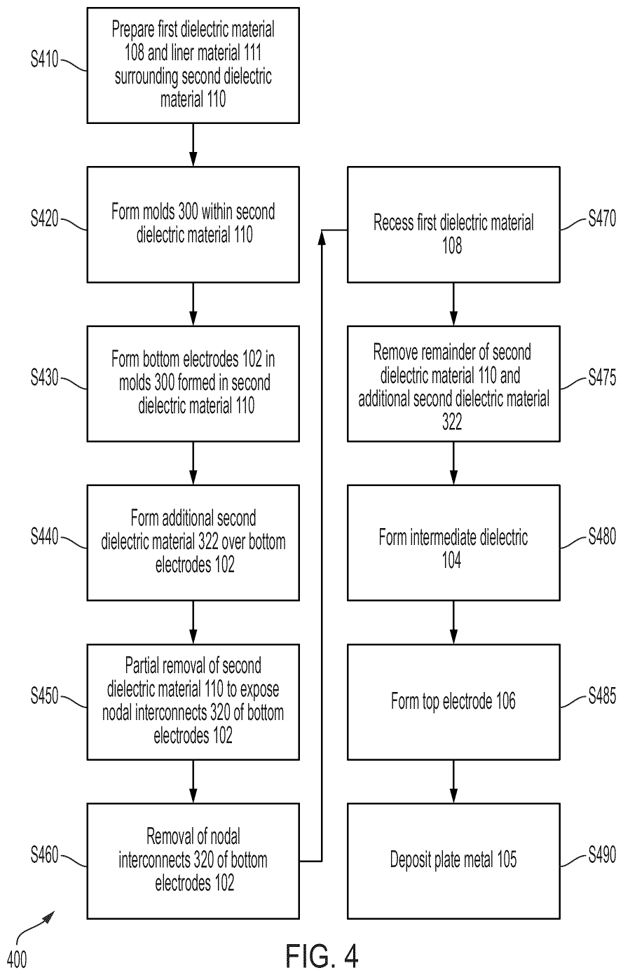

FIGS. 3A-3S depict an illustrative embodiment of a process of forming a device architecture such as the first device architecture 101, or any other device architectures shown herein. FIG. 4 depicts an example embodiment of a process 400 for forming a device architecture corresponding to the illustrative embodiment of FIGS. 3A-3S.

FIG. 3A and FIG. 3B depict S410 in the process of FIG. 4, where portions of the first device architecture 101 are prepared. FIG. 3A provides a perspective view, while FIG. 3B provides a cross-sectional view along the Z-Y plane. In the area where the one or more capacitors 100 are to be formed, portions of the first dielectric material 108, the second dielectric material 110, and the liner material 111 can be found. The first dielectric material 108, the second dielectric material 110, and the liner material 111 may be formed by any suitable process, such as chemical vapor deposition (CVD), atomic layer deposition (ALD), epitaxial growth, diffusion, or any other suitable method known in the art. As shown in the example of FIG. 3A and FIG. 3B, the second dielectric material 110 may be formed in units with the liner material 111 separating each unit vertically, while the first dielectric material 108 may surround each of unit of the second dielectric material 110 within the X-Y plane. The materials chosen for the first dielectric material 108 and the second dielectric material 110 may be chosen, at least in part, to allow for selective-removal of one of the dielectric materials without substantially effecting the other dielectric material. For example, dielectrics formed using carbides, nitrides, and oxides may respond differently to different etch processes, including both wet-etch and dry-etch processes.

FIG. 3C and FIG. 3D depict S420 in the process of FIG. 4, where one or more molds 300 is formed for later formation of the bottom electrode 102. The one or more molds 300 are openings formed within the second dielectric material 110, with portions of the liner material 111 and the first dielectric material 108 also removed. The one or more molds 300 may be formed, for example, by use of one or more etch processes, such as wet-etch processes using chemicals and dry-etch processes using reactive plasma, as well as any other suitable method of removal. In some embodiments, an etching step may be used in combination with a masking step, such as a photoresist mask formed using a lithographic process to selectively cover portions of the first device architecture 101, as well as any other suitable method for patterning the second dielectric material 110. In some embodiments, the process may be a selective etch process, and may be performed using a lateral selective etch. The one or more molds 300 may be regularly spaced apart, with each of the one or more molds 300 including a U-shaped end corresponding to the shape of the bottom electrode 102. In some embodiments, an initial removal step may remove the outer layer of first dielectric material 108, and may consist of a selective etch. A second removal step may selectively remove portions of the liner material 111. A third removal step may selectively remove portions of the second dielectric material 110. Alternatively, in some embodiments, the outer layer of the first dielectric material 108 may be selectively patterned, followed by a selective removal of the liner material 111. Portions of second dielectric material 110 may then be either removed with the liner material 111, or may be removed along with the remainder of the first dielectric material 108.

FIG. 3E depicts S430 in the process of FIG. 4, where the bottom electrode 102 is formed within the one or more molds 300. The bottom electrode 102 is a conductive material, which may include doped semiconductor materials, metals such as tungsten, functionalized carbon nanomaterials, as well as any other suitable conductive material. In some embodiments, the conductive material of the bottom electrode 102 may be formed by a semiconductor process such as CVD, ALD, PVD, electroplating, or any other suitable method for forming a conductive material. In some embodiments, the bottom electrode 102 may be formed by a conformal process to coat the exposed surfaces of the mold 300, including portions of the first dielectric material 108, the second dielectric material 110, and the liner material 111. The thickness of the bottom electrode 102 may be between 5-10 nm, although in some embodiments, the thickness may be larger or smaller, for example between 1-100 nm in thickness. The portions of the bottom electrode 102 covering the distal ends of the second dielectric material 110 may be referred to as the nodal interconnects 320. The nodal interconnections 320 may be removed in subsequent steps to isolate each bottom electrode 102 in the one or more capacitors 100.

FIG. 3F depicts S440 in the process of FIG. 4, where a second portion of the second dielectric material 110 is formed over the exposed surfaces of the bottom electrode 102 as additional second dielectric material 322. The additional second dielectric material 322 may be formed in the same manner as the second dielectric material 110. While in the example embodiment of FIG. 3F, the additional second dielectric material 322 is the same as the second dielectric material 110, in other embodiments the additional second dielectric material 322 may be formed of a different material than the second dielectric material 110. The additional second dielectric material 322 may be formed by any suitable process, such as chemical vapor deposition (CVD), atomic layer deposition (ALD), epitaxial growth, diffusion, or any other suitable method known in the art. The additional second dielectric material 322 may be formed such that any remaining space in the one or more molds 300 may be filled, with an additional layer of material formed extending outwards from the bottom electrode 102.

FIG. 3G depicts S450 in the process of FIG. 4, where the additional second dielectric material 322 may be partially removed to expose the nodal interconnections 320 of the bottom electrode 102. The additional second dielectric material 322 may be removed using any suitable semiconductor process, and may include techniques such as etching, including both wet-etch processes using chemicals and dry-etch processes using reactive plasma, as well as lithography, mechanical drilling or cutting, lasers, and a combination of these methods and any other suitable methods known in the art. In some embodiments, the process may be a selective etch process, and may be performed using a lateral selective etch.

FIG. 3H and FIG. 3I depict S460 in the process of FIG. 4, where the nodal interconnections 320 may be removed to disconnect portions of the bottom electrode 102 to create individual capacitor structures for the one or more capacitors 100. The nodal interconnections 320 may be removed using any suitable semiconductor process, and may include techniques such as etching, including both wet-etch processes using chemicals and dry-etch processes using reactive plasma, as well as lithography, mechanical drilling or cutting, lasers, and a combination of these methods and any other suitable methods known in the art. In some embodiments, the process may be a selective etch process, and may be performed using a lateral selective etch. In some embodiments, portions of the additional second dielectric material 322 may be removed with the nodal interconnections 320. In some embodiments, after removing the nodal interconnections 320, the second dielectric material 110 and the additional second dielectric material 322 may form an exterior surface. The exterior surface may, in some embodiments such as shown in FIG. 3H, be roughly planar, while in other embodiments such as shown in FIG. 3I, the additional second dielectric material 322 may extend outwards from the second dielectric material 110.

FIG. 3J depicts S470 in the process of FIG. 4, where a portion of the first dielectric material 108 may be recessed. Portions of the first dielectric material 108 may be removed using any suitable semiconductor process, and may include techniques such as etching, including both wet-etch processes using chemicals and dry-etch processes using reactive plasma, as well as lithography, mechanical drilling or cutting, lasers, and a combination of these methods and any other suitable methods known in the art. The process may be a selective etch process, and may be performed using a vertical selective etch as well as a lateral selective etch. The first dielectric material 108 may be partially removed to expose the exterior surfaces of the bottom electrode 102. The first dielectric material 108 may have portions remain to provide support for the bottom electrode 102, and to provide isolation between each of the one or more capacitors 100.

FIG. 3K, FIG. 3L and FIG. 3M depict S475 in the process of FIG. 4, where any remaining portions of the second dielectric material 110 and the additional second dielectric material 322 in contact with the bottom electrode 102 are removed. The removal of the remaining portions of the second dielectric material 110 and the additional second dielectric material 322 may be done using any suitable semiconductor process, and may include techniques such as etching, including both wet-etch processes using chemicals and dry-etch processes using reactive plasma, and any other suitable methods known in the art. The removal process may be selective such that the previously recessed portions of the first dielectric material 108 may be unaffected. In some embodiments, the process may be performed using a lateral selective etch. The example embodiment shown in FIG. 3L provides a perspective view of the bottom electrode 102 in three-dimensions, showing how in each of the one or more capacitors 100, the bottom electrode 102 may have a three-dimensional shape including multiple walls for establishing a capacitive relationship with. FIG. 3M provides a cross-sectional view showing the removal of the second dielectric material 110 exposing the U-shaped cross-sectional structure of the bottom electrode 102.

FIG. 3N and FIG. 3O depict S480 in the process of FIG. 4, where the intermediate dielectric 104 may be formed over the bottom electrode 102 and any exposed surfaces of the first dielectric material 108. The intermediate dielectric 104 may be formed by any suitable process, such as chemical vapor deposition (CVD), atomic layer deposition (ALD), or any other suitable method known in the art. In some embodiments, the intermediate dielectric 104 may consistent of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide. In some embodiments, the intermediate dielectric 104 may be formed to have a conformal coating over the bottom electrode 102 and any exposed surfaces of the first dielectric material 108, and may be formed to a thickness in the range of 5-10 nm, although in some embodiments, the thickness may be larger or smaller, for example between 1-100 nm in thickness.

FIG. 3P and FIG. 3Q depict S485 in the process of FIG. 4, where the top electrode 106 is formed over the intermediate dielectric 104 and the bottom electrode 102. The top electrode 106 is a conductive material, which may include doped semiconductor materials, metals such as tungsten, functionalized carbon nanomaterials, as well as any other suitable conductive material. In some embodiments, the conductive material of the top electrode 106 may be formed by a semiconductor process such as CVD, ALD, PVD) electroplating, or any other suitable method for forming a conductive material. In some embodiments, the top electrode 106 may be formed by a conformal process to coat the exposed surfaces of the intermediate dielectric 104. The thickness of the top electrode 106 may be between 5-10 nm, although in some embodiments, the thickness may be larger or smaller, for example between 1-100 nm in thickness.

FIGS. 3R and 3S depict S480 in the process of FIG. 4, where the plate conductor 105 is deposited on the top electrode 106. The plate conductor 105 is a conductive material, which may include metals such as tungsten, aluminum, titanium, as well as any other suitable conductive material. In some embodiments, the conductive material of the plate conductor 105 may be formed by a semiconductor process such as CVD, ALD, PVD, electroplating, or any other suitable method for forming a conductive material. In some embodiments, the plate conductor 105 may be formed of multiple layers, and may include the second plate conductor 107. In some embodiments, the plate conductor 105 may be chosen for suitability to contact the material forming the top electrode 106, while the second plate conductor 107 may form the drain line for the first device architecture 101. In some embodiments the plate conductor 105 may include one or more additional layers to form a liner layer or glue layer. In some embodiments, the plate conductor 105 may be referred to as a plug, conductive plug, or plug metal.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific example teachings discussed above, but is instead defined by the following claims.

What is claimed is:

1. A device comprising:
a first electrode forming a first structure, the first structure having a first segment and a second segment, the second segment extending in a direction parallel to the first segment;
a second electrode forming a second structure, the second structure having a third segment and a fourth segment with the first segment arranged between the third segment and the second segment, the second structure arranged concentrically with the first structure;
the first structure and the second structure forming a first capacitor;
a first dielectric material, the first dielectric material arranged on a side of the first electrode opposite the second electrode;
an intermediate dielectric material arranged between the first electrode and the second electrode, the intermediate dielectric material supporting the second electrode; and
a conductive plug contacting the second electrode,
wherein the first structure is arranged concentrically around the conductive plug.

2. The device of claim 1,
wherein the first dielectric material comprises one or more of a carbide, nitride, or oxide.

3. The device of claim 1, wherein
the first electrode is coupled to a source,
the second electrode is coupled to a drain,
a transistor is between the first electrode and the source, and
the first electrode, the second electrode, and the transistor form a memory cell.

4. The device of claim 1, wherein the intermediate dielectric material comprises a material having a higher dielectric constant than silicon oxide.

5. The device of claim 1, wherein
the intermediate dielectric material conformally covers the first electrode, and
the second electrode conformally covers the intermediate dielectric material.

6. The device of claim 1, wherein
the intermediate dielectric material conformally covers a first side of the second electrode, and
wherein the conductive plug extends on a second side of the second electrode opposite the first side and extends parallel to the intermediate dielectric material.

7. The device of claim 1, the second electrode further comprising a fifth segment and a sixth segment, the sixth segment extending in a direction parallel to the fifth segment,
wherein the second segment is arranged between the fifth segment and the sixth segment.

8. A system comprising:
a first electrode forming a first capacitive structure, the first capacitive structure contacting a first dielectric material on a first side;
a second electrode forming a second capacitive structure, the second capacitive structure having an axial opening;
a second dielectric material arranged between the first capacitive structure and the second capacitive structure, the second dielectric material located on a second side of the first capacitive structure, the second side opposite the first side; and
a conductive layer, the conductive layer forming a conductive plug within the axial opening of the second capacitive structure,
wherein the first capacitive structure and the second capacitive structure are coaxial.

9. The system of claim 8, wherein the second dielectric material comprises a material having a higher dielectric constant than silicon oxide.

10. The system of claim 8, wherein
the second dielectric material conformally coats the first electrode, the second electrode conformally coats the second dielectric material.

11. The system of claim 8, wherein
the second capacitive structure is concentric with the conductive plug.

12. The system of claim 8, further comprising a third electrode forming a third capacitive structure, wherein
the second electrode forms a fourth capacitive structure arranged coaxially with the third capacitive structure,
the second dielectric material arranged between the third capacitive structure and the fourth capacitive structure,
the fourth capacitive structure has a second axial opening, and
the conductive layer forms a second conductive plug within the second axial opening of the fourth capacitive structure.

13. The system of claim 8, wherein the first capacitive structure and the second capacitive structure form a capacitor within a memory cell of a vertically-stacked dynamic random-access memory.

14. A method comprising:
forming a mold within a first dielectric;
depositing a first conductor within the mold, the first conductor conformally coating the mold;
forming the first conductor into one or more first electrodes;
forming an intermediate dielectric over the one or more first electrodes; and
depositing a second conductor over the intermediate dielectric to form one or more second electrodes,
wherein the one or more first electrodes are separated by the first dielectric, and wherein the one or more second electrodes form a continuous layer.

15. The method of claim 14, wherein
the first dielectric comprises one or more of a carbide, nitride, or oxide, and
the intermediate dielectric comprises a material having a higher dielectric constant than silicon oxide.

16. The method of claim 14, wherein
depositing the second conductor is performed by a conformal process, and
depositing the intermediate dielectric is performed by a conformal process.

17. The method of claim 14, further comprising, after depositing the second conductor, depositing a plate conductor layer over the second conductor.

18. The method of claim 14, wherein forming the first conductor into the one or more first electrodes includes removing portions of the first conductor between each of the one or more first electrodes.

19. The method of claim 14, wherein forming the mold within the first dielectric is done in a lateral direction.

20. The method of claim 14, wherein the intermediate dielectric forms a continuous layer between the one or more first electrodes and the one or more second electrodes.
